(19) United States
(12) Patent Application Publication
(10) Pub. No.: US 2021/0265522 A1
(43) Pub. Date: Aug. 26, 2021

(54) MICRO LED TRANSFER METHOD AND DISPLAY DEVICE USING SAME

(71) Applicant: POINT ENGINEERING CO., LTD., Asan (KR)

(72) Inventors: Bum Mo AHN, Suwon (KR); Seung Ho PARK, Hwaseong (KR); Sung Hyun BYUN, Hwaseong (KR)

(21) Appl. No.: 17/253,965

(22) PCT Filed: Feb. 13, 2020
(86) PCT No.: PCT/KR2020/001997

§ 371 Date: Dec. 18, 2020

(30) Foreign Application Priority Data
Feb. 26, 2019 (KR) 10-2019-0022486

(51) Int. Cl. H01L 33/00; H01L 25/075; H01L 33/62

(52) U.S. Cl. CPC H01L 33/005; H01L 2933/0066; H01L 33/62; H01L 25/0753

(57) ABSTRACT

Proposed are a micro LED transfer method of transferring micro LEDs of a first substrate to a second substrate and a micro LED display device using the same. More particularly, proposed are a micro LED transfer method capable of manufacturing a micro LED display device by transferring a normal individualized module to a second substrate, and a micro LED display device using the same.

### RELATED APPLICATIONS

This application is a National Phase of International Application No. PCT/KR2020/001997 filed Feb. 13, 2020, which claims priority to Korean Patent Application No. KR 10-2019-0022486 filed Feb. 26, 2019, the disclosures of which are incorporated herein by reference.

### TECHNICAL FIELD

The present disclosure relates to a transfer method of transferring micro light-emitting diodes (LEDs) of a first substrate to a second substrate, and a display device using the same.

### BACKGROUND ART

Currently, the display market remains dominated by LCDs, but OLEDs are quickly replacing LCDs and emerging as mainstream products. In the current situation in which display makers are rushing to participate in the OLED market, micro light-emitting diode (hereinafter, referred to as ‘micro LED’) displays have emerged as another type of next generation display. Liquid crystal and organic materials are the core materials of LCDs and OLEDs, respectively, whereas the micro LED display uses 1 μm to 100 μm LED chips themselves as a light emitting material.

A display using micro LEDs may be fabricated by connecting a plurality of micro LED elements to a circuit board.

A manufactured electronic component is checked for defects in the course of checking the performance. An element identified as defective in the course of checking the performance is removed from a printed circuit board and undergoes a repair process in which the defective element is replaced with a normal one.

An example of a patent for such a defective element repair process is described in Korean Patent No. 10-1918106 (hereinafter, referred to as ‘Patent Document 1’).

In Patent Document 1, only a defective element existing on a substrate can be selectively replaced by using a repair apparatus including a first adhesive film, a pressuring part, and a second adhesive film. In Patent Document 1, the defective element on the substrate is replaced with a replacement element by performing a pressurizing step of pressurizing the first adhesive film to bring the first adhesive film into intimate contact with the defective element, a defective element removal step of removing the defective element adhered to the first adhesive film from the substrate, and a replacement element bonding step of bonding the replacement element to a position where the defective element is removed from the substrate.

However, in Patent Document 1, there is a need to perform a repair process for each defective element from among the micro elements arranged on the substrate. In the case of a micro element, since the size is very small, it may be cumbersome to remove each defective element individually and replace the same with the replacement element. In addition, when the replacement element is defective, there is an inconvenience in that there is a need to repeat the repair process.

Furthermore, Patent Document 1 is problematic in that while performing the repair process on one defective element of very small size, even normal elements in the vicinity of the defective element may be interfered. In Patent Document 1, the first adhesive film may be pressurized to adhere the defective element to the first adhesive film. Tens of thousands to hundreds of thousands of micro elements are transferred on the substrate at narrow pitches. Therefore, an adhesion error problem in which normal elements in the vicinity of the defective element are adhered to the first adhesive film during the adhesion process may occur. As a result, an error in the defective element repair process may occur, which may reduce process efficiency of manufacturing a finished display product.

Patent Document 1 is further problematic in that when a plurality of defective elements are detected on the substrate, the repair process needs to be performed for each of the plurality of defective elements, which may reduce manufacturing efficiency of the entire process for manufacturing a finished display product. As a result, the units per hour (UPH) rate in production of the finished display product may be reduced.

### DOCUMENTS OF RELATED ART

[Patent Document]

(Patent Document 1) Korean Patent No. 10-1918106

### DISCLOSURE

### Technical Problem

Accordingly, the present disclosure has been made keeping in mind the above problems occurring in the related art, and an objective of the present disclosure is to provide a micro LED transfer method capable of increasing efficiency of a process for manufacturing a display device by performing a repair process to replace a defective micro LED in the form of an individualized module, and provide a display device using the same.

### Technical Solution

In order to accomplish the above objective, the present disclosure provides a micro LED transfer method, including: transferring micro LEDs of a first substrate to a relay wiring substrate provided with a relay wiring part; cutting the relay wiring substrate to which the micro LEDs are transferred into a plurality of individualized modules; and transferring a normal individualized module among the individualized modules to a second substrate.

Furthermore, the transferring of the normal individualized module may be performed by collectively transferring, by a transfer head, a plurality of normal individualized modules including the normal individualized module in which a defective individualized module is replaced with a normal individualized module by a repair head to the second substrate.

Furthermore, the transferring of the normal individualized module may be performed by individually transferring, by a transfer head, only the individualized module to the second substrate.

Furthermore, the micro LED transfer method may further include: molding an upper portion of the relay wiring substrate after the transferring of the micro LEDs.

Furthermore, the micro LED transfer method may further include: testing the micro LEDs by applying electricity to the relay wiring part, wherein an individualized module with a normal micro LED may be specified as a normal individualized module.

Furthermore, the testing of the micro LEDs may be performed after the transferring of the micro LEDs or the cutting of the relay wiring substrate.

According to another aspect of the present disclosure, there is provided a micro LED display device, including: a circuit board provided with a circuit wiring part; and an individualized module electrically connected to the circuit wiring part on an upper surface of the circuit board, and provided with micro LEDs located on a relay wiring substrate provided with a relay wiring part so as to be electrically connected to the relay wiring part.

Furthermore, the individualized module may be provided discontinuously on the circuit board.

Furthermore, the micro LED may be a flip-chip micro LED.

### Advantageous Effects

According to the micro LED transfer method according to the present disclosure and the display device using the same, it is possible to rapidly perform the process for manufacturing a finished product by efficiently performing the process of replacing a defective micro LED with a normal micro LED, thereby improving the UPH in production of a finished product.

### DESCRIPTION OF DRAWINGS

FIG. 1 is a view illustrating micro LEDs to be transferred by an embodiment of the present disclosure;

FIGS. 2A, 2B, 2C_1, and 2C_2 are views sequentially illustrating a micro LED transfer method according to an embodiment of the present disclosure;

FIGS. 3A and 3B are views schematically illustrating an intermediate process of FIG. 2C_1;

FIG. 4 is a view schematically illustrating a micro LED display device according to an embodiment of the present disclosure;

FIG. 5 is a view illustrating FIG. 4 as viewed from above; and

FIGS. 6A and 6B are views illustrating a pixel arrangement of an individualized module of the present disclosure.

### MODE FOR INVENTION

Contents of the description below merely exemplify the principle of the present disclosure. Therefore, those of ordinary skill in the art may implement the theory of the present disclosure and invent various apparatuses which are included within the concept and the scope of the present disclosure even though it is not clearly explained or illustrated in the description. Furthermore, in principle, all the conditional terms and embodiments listed in this description are intended for the purpose of understanding the concept of the present disclosure clearly, and one should understand that this invention is not limited the exemplary embodiments and the conditions.

The above described objectives, features, and advantages will be more apparent through the following detailed description related to the accompanying drawings, and thus those of ordinary skill in the art may easily implement the technical spirit of the present disclosure.

The embodiments of the present disclosure will be described with reference to cross-sectional views and/or perspective views which schematically illustrate ideal embodiments of the present disclosure. For explicit and convenient description of the technical content, sizes or thicknesses of films and regions and diameters of holes in the figures may be exaggerated. Therefore, variations from the shapes of the illustrations as a result, for example, of manufacturing techniques and/or tolerances, are to be expected. In addition, a limited number of multiple micro LEDs are illustrated in the drawings. Thus, the embodiments should not be construed as limited to the particular shapes of regions illustrated herein but are to include deviations in shapes that result, for example, from manufacturing.

Wherever possible, the same reference numerals will be used throughout different embodiments and the description to refer to the same or like elements or parts. In addition, the configuration and operation already described in other embodiments will be omitted for convenience.

Hereinafter, exemplary embodiments of the present disclosure will be described in detail with reference to the accompanying drawings.

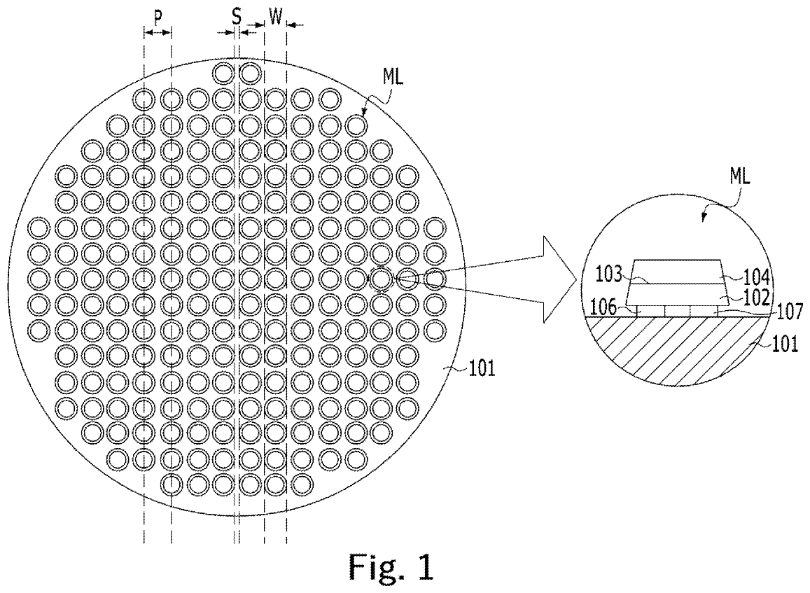

FIG. 1 is a view illustrating micro LEDs mounted on a micro LED structure according to an embodiment of the present disclosure. The micro LEDs ML are fabricated and disposed on a growth substrate 101.

The micro LEDs ML emit light having wavelengths of different colors such as red, green, blue, white, and the like. With the micro LEDs ML, it is possible to realize white light by using a fluorescent material or by combining colored lights. Each of the micro LEDs ML has a size of 1 μm to 100 μm.

The growth substrate 101 may be embodied by a conductive substrate or an insulating substrate. For example, the growth substrate 101 may be made of at least one selected from among the group consisting of sapphire (Al₂O₃), SiC, Si, GaAs, GaN, ZnO, Si, GaP, InP, Ge, and Ga₂0₃.

Each of the micro LEDs ML may include: a first semiconductor layer 102; a second semiconductor layer 104; an active layer 103 provided between the first semiconductor layer 102 and the second semiconductor layer 104; a first contact electrode 106; and a second contact electrode 107.

The first semiconductor layer 102, the active layer 103, and the second semiconductor layer 104 may be formed by performing metalorganic chemical vapor deposition (MOCVD), chemical vapor deposition (CVD), plasma-enhanced chemical vapor deposition (PECVD), molecular-beam epitaxy (MBE), hydride vapor phase epitaxy (HVPE), or the like.

The first semiconductor layer 102 may be implemented, for example, as a p-type semiconductor layer. A p-type semiconductor layer may be made of a semiconductor material having a composition formula of InxAlyGa1−x−yN (0≤x≤1, 0≤y≤1, 0≤x+y≤1) selected from among, for example, GaN, AlN, AlGaN, InGaN, InN, InAlGaN, AlInN, and the like, and the layer may be doped with a p-type dopant such as Mg, Zn, Ca, Sr, or Ba. The second semiconductor layer 104 may be implemented, for example, as an n-type semiconductor layer. An n-type semiconductor layer may be made of a semiconductor material having a composition formula of InxAlyGa1−x−yN (0≤x≤1, 0≤y≤1, 0≤x+y≤1) selected from among, for example, GaN, AlN, AlGaN, InGaN, InN, InAlGaN, AlInN, and the like, and the layer may be doped with an n-type dopant such as Si, Ge, or Sn.

However, the present disclosure is not limited to this. The first semiconductor layer 102 may be implemented as an n-type semiconductor layer, and the second semiconductor layer 104 may be implemented as a p-type semiconductor layer.

The active layer 103 is a region where electrons and holes are recombined. As the electrons and the holes are recombined, the active layer 103 transits to a low energy level and generates light having a wavelength corresponding thereto. The active layer 103 may be made of a semiconductor material having a composition formula of InxAlyGa1−x−yN (0≤x≤1, 0≤y≤1, 0≤x+y≤1) and may have a single quantum well structure or a multi quantum well (MQW) structure. In addition, the active layer 103 may have a quantum wire structure or a quantum dot structure.

The first contact electrode 106 and the second contact electrode 107 may be provided on the first semiconductor layer 102. The first contact electrode 106 and/or the second contact electrode 107 may be made of various conductive materials including a metal, conductive oxide, and conductive polymer.

In FIG. 1, the letter ‘P’ denotes a pitch distance between the micro LEDs ML, ‘S’ denotes a separation distance between the micro LEDs ML, and ‘W’ denotes a width of each micro LED ML.

The micro LEDs ML to be transferred by the present disclosure as described above with reference to FIG. 1 may be flip-chip micro LEDs.

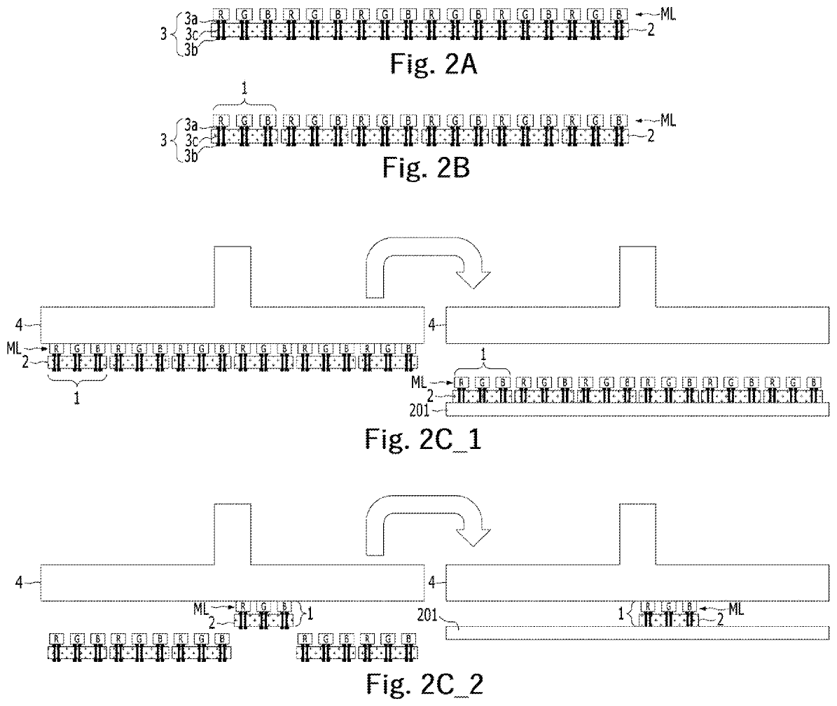

FIGS. 2A, 2B, 2C_1, and 2C_2 are views sequentially illustrating a micro LED transfer method according to an embodiment of the present disclosure. The micro LED transfer method according to the present disclosure includes a first step of transferring micro LEDs ML of a first substrate 101 to a relay wiring substrate 2, a second step of cutting the relay wiring substrate 2 into a plurality of individualized modules 1, and a third step of transferring a normal individualized module 6 to a second substrate 201.

The micro LED transfer method according to the present disclosure may be performed by a micro LED transfer system including a transfer head 4 for transferring the micro LEDs ML of the first substrate 101 to the relay wiring substrate 2 and the second substrate 201, the individualized modules 1 each having a relay wiring substrate 2 and a micro LED ML, and a repair head 7 for replacing a defective individualized module 5 with the normal individualized module 6.

The transfer head 4 is a configuration for holding and transferring the micro LEDs ML, and examples of holding force that the transfer head 4 uses to hold the micro LEDs ML may include electrostatic force, electromagnetic force, magnetic force, suction force, Van der Waals force, and bonding force that can be lost due to heat or light, but are not limited thereto.

The first substrate 101 may be the growth substrate 101 described above with reference to FIG. 1, and will be described below by being given the same reference numeral as the growth substrate 101.

The second substrate 201 is a configuration for receiving the micro LEDs ML of the first substrate 101 from the transfer head 4, and may be provided on an upper surface thereof with solder bumps 8 to which connection pads 3b of the individualized modules 1 are attached. The second substrate 201 may be configured as a circuit board 201 on which the micro LEDs ML are finally mounted. Therefore, the second substrate 201 may be a circuit board 201 having a circuit wiring part therein.

The relay wiring substrate 2 may include relay wiring parts 3 each being composed of an internal wiring 3c provided in the relay wiring substrate 2, a bonding pad 3a provided on an upper surface of the relay wiring substrate 2, and a connection pad 3b provided on a lower surface of the relay wiring substrate 2. The micro LEDs ML transferred to the relay wiring substrate 2 may be provided as flip-chip micro LEDs. Each of the micro LEDs ML transferred to the relay wiring substrate 2 may be bonded to each of the respective the bonding pads 3a provided on the upper surface of the relay wiring substrate 2. The state in which the micro LEDs ML are transferred and bonded to the relay wiring substrate 2 is a state before the micro LEDs ML of the relay wiring substrate 2 are divided for each minimum pixel unit to form the individualized modules 1, and this state may be a single structure.

Each of the individualized modules 1 may be composed of the relay wiring substrate 2 and the micro LED ML. The individualized modules 1 may be formed by dividing the micro LEDs ML of the relay wiring substrate 2 for each minimum pixel unit. Therefore, each of the individualized modules 1 may be composed of a unitized relay wiring substrate 2 and micro LEDs ML of a minimum pixel unit.

The individualized module 1 may be composed of the relay wiring substrate 2 and the micro LEDs ML of the minimum pixel unit. A detailed description thereof will be given later in the description of the second step described with reference to FIG. 2B.

The repair head 7 is a configuration for replacing the defective individualized module 5 from among the individualized modules 1 with the normal individualized module 6, and may perform the replacement by holding the defective individualized module 5 and the normal individualized module 6. Examples of holding force that the repair head 7 uses to hold the defective individualized module 5 and the normal individualized module 6 may include electrostatic force, electromagnetic force, magnetic force, suction force, Van der Waals force, and bonding force that can be lost due to heat or light, but are not limited thereto.

In the micro LED transfer system for performing the micro LED transfer method according to the present disclosure, the micro LEDs ML of the first substrate 101 may be transferred onto the relay wiring substrate 2 before transfer to the second substrate 201 to thereby form the individualized modules 1, and then the individualized modules 1 may be tested for defects so that only normal micro LEDs ML may be transferred to the second substrate 201.

The first step of the micro LED transfer method according to the present disclosure, transferring the micro LEDs ML of the first substrate 101 to the relay wiring substrate 2 provided with the relay wiring parts 3, will be described with reference to FIG. 2A. As illustrated in FIG. 2A, the micro LEDs ML of the first substrate 101 may be transferred to the relay wiring substrate 2.

The micro LEDs ML may be transferred by the transfer head 4 so that first and second contact electrodes 106 and 107 of each of the micro LEDs ML may be brought into contact with each of the bonding pads 3a provided on the upper surface of the relay wiring substrate 2. The micro LEDs ML may be bonded to the relay wiring substrate 2 by the bonding pads 3a to be electrically connected to the relay wiring substrate 2.

As illustrated in FIG. 2A, by transferring the micro LEDs ML to the relay wiring substrate 2 in the first step, a single structure in which the micro LEDs ML are bonded to the relay wiring substrate 2 may be formed.

After the first step of transferring the micro LEDs ML to the relay wiring substrate 2, a step of molding an upper portion of the relay wiring substrate 2 (hereinafter, referred to as “molding part forming step”) may be performed. This molding part forming step may be selectively performed.

When performing the molding part forming step, a molding part may be formed in a form covering the micro LEDs ML of the relay wiring substrate 2. The molding part may improve flatness of the upper portion of the relay wiring substrate 2 onto which the micro LEDs ML are transferred, and may function as a light diffusion layer. In addition, since the molding part fixes each adjacent micro LEDs ML to each other, the micro LEDs ML are fixed in position without being moved during transfer of the individualized modules 1, and since the molding part covers upper surfaces of the micro LEDs ML, direct contact between the transfer head 4 and the micro LEDs ML may be prevented, thereby preventing damage to the micro LEDs ML during transfer of the individualized modules 1. The molding part may increase light extraction efficiency by scattering light emitted from the micro LEDs ML. When the molding part forming step is performed to form the molding part on the relay wiring substrate 2, the structure may include the relay wiring substrate 2, the micro LEDs ML, and the molding part. In addition, when the structure is cut to form the individualized modules 1, the individualized modules 1 may include the unitized relay wiring substrate 2, the micro LEDs ML of the minimum pixel unit, and a molding part.

Then, as illustrated in FIG. 2B, the second step may be performed. In the second step, a process of cutting the relay wiring substrate 2 to which the micro LEDs ML are transferred into the plurality of individualized modules 1 may be performed. As a method of cutting the relay wiring substrate 2, a conventional wiring substrate cutting method may be used.

The relay wiring substrate 2 may be cut into the plurality of individualized modules 1 for each minimum pixel unit of the micro LEDs ML transferred to the relay wiring substrate 2. The arrangement of the micro LEDs ML transferred to the relay wiring substrate 2 may be determined depending on the arrangement of holding portions of the transfer head 4 transferring the micro LEDs ML of the first substrate 101 to the relay wiring substrate 2. The holding portions are configurations included in the transfer head 4 and may be configured to directly hold the micro LEDs ML. Accordingly, the micro LEDs ML held on the transfer head 4 according to the arrangement of the holding portions may be transferred to the relay wiring substrate 2 in an arrangement corresponding to the arrangement the holding portions.

For example, the transfer head 4 holds the micro LEDs ML using vacuum suction force. In this case, the holding portions of the transfer head 4 may be configured as a plurality of holding holes. The holding holes may be formed at a three-fold pitch distance of an x-direction pitch distance of the micro LEDs ML arranged on the relay wiring substrate 2 illustrated in FIG. 2A. Through the arrangement of the holding holes, the transfer head 4 may transfer respective red micro LEDs R, green micro LEDs G, and blue micro LEDs B to the relay wiring substrate 2 at a three-fold pitch distance in the x-direction.

In the second step, the relay wiring substrate 2 may be cut for each minimum pixel unit of the micro LEDs ML including the red micro LEDs R, the green micro LEDs G, and the blue micro LEDs B transferred to the relay wiring substrate 2 at a three-fold pitch distance in the x-direction. In this case, the three-fold pitch of the micro LEDs ML in the x-direction illustrated in FIGS. 2A, 2B, 2C_1, and 2C_2 have been described as only an example. Thus, the micro LEDs ML on the relay wiring substrate 2 may be transferred in a different arrangement order.

Hereinafter, in the description with reference to FIGS. 2A to 5, it will be described that the micro LEDs ML are transferred to the relay wiring substrate 2 at a three-fold pitch in the x-direction.

After the second step of cutting the relay wiring substrate 2 into the plurality of individualized modules 1 as illustrated in FIG. 2B, a testing step of testing the micro LEDs ML by applying electricity to the relay wiring parts 3 of the relay wiring substrate 2 may be performed. Through the testing step, it is checked whether the micro LEDs ML are defective, and an individualized module 1 with a normal micro LED is specified from among the plurality of individualized modules 1 formed in the second step.

When the testing step is performed after the second step of cutting the relay wiring substrate 2 into the plurality of individualized modules 1, in the testing step, the micro LEDs ML provided in the plurality of individualized modules 1 may be tested. In detail, electricity is applied to the plurality of individualized modules 1 to check which of the individualized modules 1 includes a defective micro LED F from among the micro LEDs ML provided in the respective individualized modules 1. Thus, a normal individualized module 6 is specified from among the plurality of individualized modules 1.

Meanwhile, the testing step may be performed after the first step of transferring the micro LEDs ML of the first substrate 101 to the relay wiring substrate 2. In other words, the testing step may be performed on the structure formed after performing the first step.

As described above, when the testing step is performed after the second step of cutting the relay wiring substrate 2 into the plurality of individualized modules 1, a process in which the micro LEDs ML of the plurality of individualized modules 1 are tested in a state in which the plurality of individualized modules 1 are formed to thereby specify the normal individualized module may be performed. This may be achieved by testing the micro LEDs ML of the plurality of individualized modules 1 to check which of the plurality of individualized modules 1 includes the defective micro LED F.

When the testing step is performed after the first step, the position of the defective micro LED F on the relay wiring substrate 2 may be identified before forming the plurality of individualized modules 1. Thus, before performing the second step, which of the plurality of individualized modules 1 in the second step will be the normal individualized module is specified in advance and the second step is then performed.

According to the present disclosure, by performing the testing step, the normal individualized module that does not include the defective micro LED F is specified.

Then, the third step of transferring the normal individualized module 6 from among the individualized modules 1 to the second substrate 201 may be performed. As a method of transferring the normal individualized module 6 to the second substrate 201 in the third step, a method of collectively transferring a plurality of normal individualized modules 6 or a method of individually transferring each of the plurality of normal individualized modules 6 may be used.

First, the method of collectively transferring the plurality of normal individualized modules 6 to the second substrate 201 will be described with reference to FIG. 2C_1.

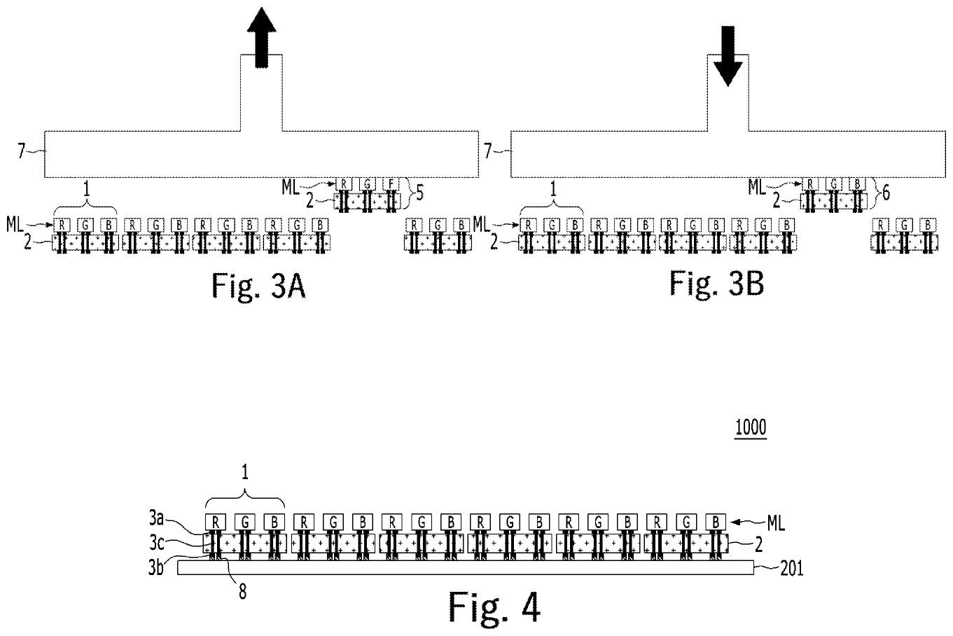

As illustrated in FIG. 2C_1, the transfer head 4 may collectively hold the plurality of individualized modules 6 and transfer the same to the second substrate 201. Before the transfer head 4 collectively holds the plurality of individualized modules 6, a process of configuring the plurality of individualized modules 1 with only a plurality of normal individualized modules 6 may be performed. This will be described in detail with reference to FIGS. 3A and 3B.

When the third step is a step of collectively transferring the plurality of normal individualized modules 6 to the second substrate 201, as illustrated in FIGS. 3A and 3B, a process in which the defective individualized module 5 is replaced with the normal individualized module 6 by the repair head 7 may be performed.

FIG. 3A illustrates a state in which the defective individualized module 5 is held on the repair head 7, the defective individualized module being formed by specifying the defective individualized module 5 including the defective micro LED F in the testing step and by cutting the relay wiring substrate 2 into the plurality of individualized modules 1. In this case, although FIG. 3A illustrates one defective individualized module 5, the number of the defective individualized modules 5 is not limited thereto. In addition, although FIG. 3A illustrates that one defective micro LED F is included in the defective individualized module 5, a plurality of defective micro LEDs F may be included.

The repair head 7 may receive the position of the defective individualized module 5 specified in the testing step from a controller (not illustrated). Thus, the repair head 7 may hold only the defective individualized module 5 from among the plurality of individualized modules 1.

The remaining plurality of individualized modules 1 that are not held on the repair head 7 illustrated in FIG. 3A may be normal individualized modules 6.

The repair head 7 may hold and remove the defective individualized module 5 from among the plurality of individualized modules 1. A spare normal individualized module 6 may be transferred to the position of the removed defective individualized module 5. The spare normal individualized module 6 which replaces the defective individualized module 5 may be held or removed using the same repair head 7 as the repair head 7 for holding and removing the defective individualized module 5 or using a separate repair head 7 for holding the spare normal individualized module 6.

As illustrated in FIG. 3B, the repair head 7 may transfer the spare normal individualized module 6 to a position where the defective individualized module 5 is removed.

As described above, in the present disclosure, during replacement, the defective individualized module 5 itself including the defective micro LED F may be replaced with the normal individualized module 6 without the need to individually remove each micro LED identified as defective and replace the same with another micro LED. Thus, as illustrated in FIG. 2C_1, the plurality of normal individualized modules 6 may be held and collectively transferred to the second substrate 20.

In the related art, each micro LED identified as defective is removed individually and replaced with a spare micro LED. In this case, the removal process is cumbersome due to the small size of the micro LED, and a problem of reducing efficiency of manufacturing a finished product is caused. In addition, in the related art, a repair process is performed without checking whether the spare micro LED replacing the removed defective micro LED F is defective. Thus, when the spare micro LED is defective, there is a need to repeatedly perform a cumbersome replacement process, which is inconvenient.

However, in the present disclosure, the relay wiring substrate 2 is cut for each minimum pixel unit of the micro LEDs ML to form the individualized modules 1, and when an individualized module 1 with the defective micro LED F exists from among the individualized modules 1, this individualized module 1 may be distinguished as the defective individualized module 5 and removed. In other words, the defective individualized module 5 itself including the defective micro LED F is removed in the form of an individualized module without the need to individually remove each defective micro LED F. The normal individualized module 6 is transferred to the position where defective individualized module 5 is removed and replaces the defective individualized module 5.

As described above, in the present disclosure, the removal process for replacement may be facilitated compared to the process of removing and replacing one micro LED of a very small size as in the related art. Therefore, a rapid process is possible. As a result, process time for manufacturing a finished product is shortened, thereby improving manufacturing efficiency.

In addition, the normal individualized module 6 replacing the defective individualized module 5 removed in the replacement process of FIGS. 3A and 3B may be an individualized module specified as the normal individualized module 6 by testing the micro LEDs ML in the testing step. Therefore, the normal individualized module 6, which has been checked for defects before performing the step of transferring the individualized modules 1 to the second substrate 201 in the third step, is used as a replacement for the defective individualized module 5. Therefore, there is no possibility of defects of a replacement micro LED, and there is no need to perform a repetitive replacement process.

Referring to FIG. 2C_1 again, after the process of replacing the defective individualized module 5 with the normal individualized module 6 is performed by the repair head 7 as illustrated in FIGS. 3A and 3B, the transfer head 4 may hold the plurality of normal individualized modules 6 and collectively transfer the same to the second substrate 201. A device manufactured using the second substrate 201 to which only the normal individualized modules 6 are transferred through this process may have a high degree of reliability.

Meanwhile, as a method of transferring the normal individualized module 6 to the second substrate 201 in the third step, a method of individually transferring each of the plurality of normal individualized modules 6 may be used. This will be described with reference to FIG. 2C_2.

As illustrated in FIG. 2C_2, the transfer head 4 may individually transfer only the normal individualized modules 6 to the second substrate 201. The transfer head 4 may hold the individualized modules 6 to be transferred to the second substrate 201 in a one-by-one manner. The transfer head 4 may perform a process of receiving the position of one normal individualized module 6 to be held from the controller and holding the normal individualized module 6. The transfer head 4 may transfer the held one normal individualized module 6 to the second substrate 201. The normal individualized modules 6 which are held in a one-by-one manner by the transfer head 4 and individually transferred to the second substrate 201 may be normal individualized modules 6 that have been checked for defects through the testing step.

The micro LED transfer method according to the present disclosure performed by the above process may efficiently perform a repair process by forming the individualized modules 1 without individually replacing each defective micro LED F. As a result, this allows the process for manufacturing a finished product to be rapidly performed, thereby improving the UPH in production of the finished product.

FIG. 4 is a view schematically illustrating a micro LED display device 1000 according to an embodiment of the present disclosure. As illustrated in FIG. 4, the micro LED display device 1000 according to the present disclosure may include a circuit board 201 provided with a circuit wiring part, and an individualized module 1 provided with micro LEDs ML on a relay wiring substrate 2 provided with relay wiring parts 3 so as to be electrically connected to the relay wiring parts 3.

The circuit wiring part may be provided in the circuit board 201. The circuit wiring part of the circuit board 201 may be electrically connected to second connection pads 3b of the relay wiring substrate 2 which will be described later. The circuit wiring part of the circuit board 201 and the second connection pads 3b of the relay wiring substrate 2 may be joined together by solder bumps 8 provided on an upper surface of the circuit board 201 and electrically connected to each other.

As illustrated in FIG. 4, the solder bumps 8 may be provided on the upper surface of the circuit board 201. The solder bumps 8 may be provided on the upper surface of the circuit board 201 so as to correspond to second connection pads 3b of a plurality of individualized modules 1 provided on the circuit board 201. The individualized modules 1 may be transferred so that the second connection pads 3b may be brought into contact with the solder bumps 8 when transferred to the circuit board 201. Then, the plurality of individualized modules 1 may be soldered and electrically connected to the circuit board 201.

Each of the individualized modules 1 may include a relay wiring substrate 2 and micro LEDs ML. In FIG. 4, the individualized module 1 is illustrated as including the relay wiring substrate 2 and the micro LEDs ML, but when a molding part is provided on the relay wiring substrate 2, the individualized module 1 includes the relay wiring substrate 2, the micro LEDs ML, and the molding part.

The individualized modules 1 may be formed by transferring the micro LEDs ML to the relay wiring substrate 2 before cutting and by dividing the micro LEDs ML for each minimum pixel unit. Thus, when the plurality of individualized modules 1 are transferred to the circuit board 201 and arranged adjacent to each other, pixel units are repeatedly arranged to implement pixels.

The relay wiring substrate 2 constituting each of the individualized modules 1 may be in the form of a unitized relay wiring substrate resulting from cutting the relay wiring substrate 2 for each minimum pixel unit of the micro LEDs ML.

The relay wiring substrate 2 may include first connection pads 3a on an upper surface thereof and second connection pads 3b on a lower surface thereof.

Each of the first connection pads 3a may be provided to correspond to first and second contact electrodes 106 and 107 of each of flip-chip micro LEDs ML transferred to the relay wiring substrate 2. Thus, the micro LEDs ML transferred to the relay wiring substrate 2 may be electrically connected to the relay wiring substrate 2. The micro LEDs ML transferred to the relay wiring substrate 2 may be soldered thereto. In this case, a solder bumps may be provided on each of the first connection pads 3a of the relay wiring substrate 2 or may be provided on a lower surface of each of the respective first and second contact electrodes 106 and 107 of the micro LEDs ML.

The second connection pads 3b may be joined to the circuit wiring part with the solder bumps 8 provided to correspond to the second connection pads 3b on the upper surface of the circuit board 201, so that the individualized modules 1 and the circuit board 201 may be electrically connected to each other.

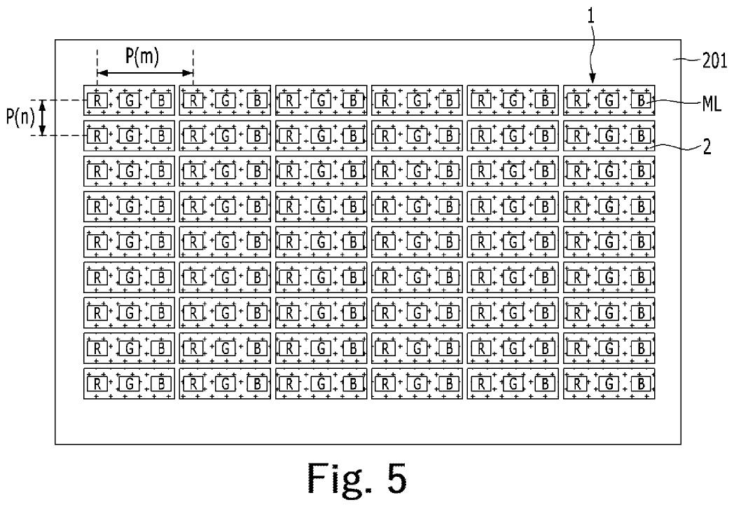

FIG. 5 is a view illustrating the micro LED display device 1000 according to the present disclosure as viewed from above. The micro LEDs ML illustrated in FIG. 5 are illustrated as having a rectangular shape in horizontal cross-section, but as illustrated in FIG. 1, the micro LEDs ML may have a circular shape in the horizontal cross-section.

As illustrated in FIG. 5, the individualized modules 1 may be discontinuously provided on the circuit board 201. The individualized modules 1 illustrated in FIG. 5 may be formed by arranging red micro LEDs R, green micro LEDs G, and blue micro LEDs B in one-dimensional arrays on the relay wiring substrate 2 and by cutting the relay wiring substrate 2 for each minimum pixel unit.

The individualized modules 1 illustrated in FIG. 5 may be formed by transferring the respective red, green, and blue micro LEDs R, G, and B to the relay wiring substrate 2 at a three-fold pitch distance P (m) in the x-direction and at a one-fold pitch distance P (n) in the y-direction and by cutting the relay wiring substrate 2 for each minimum pixel unit composed of a 3×1 pixel arrangement.

In order to form the individualized modules 1, the red micro LEDs R, the green micro LEDs G, and the blue micro LEDs B may be sequentially transferred to the relay wiring substrate 2. This is an example, and thus the transfer order of the micro LEDs ML is not limited thereto. Hereinafter, the micro LEDs ML will be described as being transferred in the order of the red micro LEDs R, the green micro LEDs G, and the blue micro LEDs B.

As illustrated in FIG. 5, before the individualized modules 1 are formed, a transfer head 4 may hold the red micro LEDs R from a first red micro LED substrate with the red micro LEDs R, and transfer the red micro LEDs R to the relay wiring substrate 2. In this case, the transfer head 4 that holds the red micro LEDs R may have holding holes formed at a three-fold pitch distance in the x-direction and at a one-fold pitch distance in the y-direction, or holding holes formed at a one-fold pitch distance in the x-direction and at a one-fold pitch distance in the y-direction. The transfer head 4 may generate holding force selectively only in columns to be held (vertical direction) to transfer the red micro LEDs R. The transfer head 4 for transferring the red micro LEDs R may be used to transfer the green and blue micro LEDs G and B which will be described later.

Then, in the same manner as in the case of the red micro LEDs R, the transfer head 4 may hold the green micro LEDs G from a first green micro LED substrate with the green micro LEDs G and transfer the same to the relay wiring substrate 2, and then may hold the blue micro LEDs B from a first blue micro LED substrate with the blue micro LEDs B and transfer the same to the relay wiring substrate 2.

As above, the transfer head 4 may transfer the red, green, and blue micro LEDs R, G, and B to the relay wiring substrate 2 while reciprocating three times between the respective first substrates 101 with the micro LEDs R, G, and B and the relay wiring substrate 2 so that three red, green, and blue micro LEDs R, G, and B may form a 3×1 pixel arrangement.

As illustrated in FIG. 5, the order of the pixel arrangement of an individualized module 1 in row 1 and column 1 located on the leftmost side in the drawing is such that a red micro LED R, a green micro LED G, and a blue micro LED B are sequentially arranged in a row.

Individualized modules 1 each having the same arrangement order as this arrangement order are repeatedly arranged in the column direction (vertical direction) and the row direction (horizontal direction) in number corresponding to a natural number multiple, so that the individualized modules 1 in rows and columns in FIG. 5 have the same pixel arrangement order.

Meanwhile, when the micro LEDs ML of the relay wiring substrate 2 are divided for each minimum pixel unit to form the individualized modules 1, the individualized modules 1 may be formed in number corresponding to a natural number multiple of the minimum pixel unit. If the individualized modules 1 illustrated in FIG. 5 are individualized modules 1 that are formed by transferring the micro LEDs ML to the relay wiring substrate 2 to form 3×1 pixel arrangements and by dividing the micro LEDs ML for each minimum pixel unit, the individualized modules 1 may be formed in number corresponding to 3m×n. In this case, m and n are natural numbers.

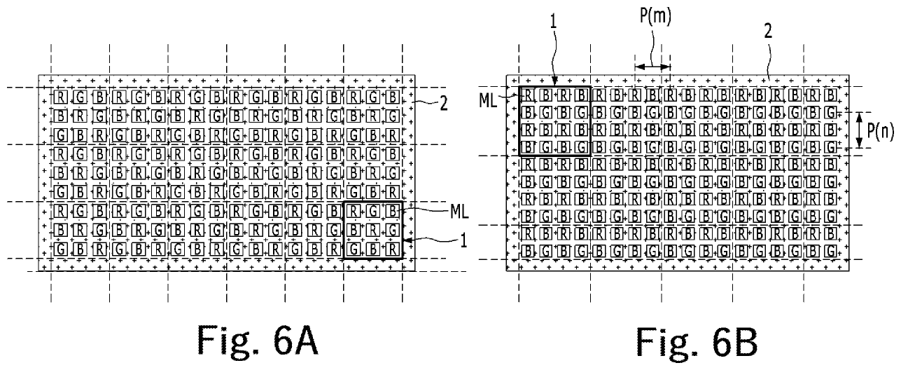

The individualized modules 1 may be formed by transferring the micro LEDs ML to the relay wiring substrate 2 to form a pixel arrangement different from that illustrated in FIG. 5 and by dividing the micro LEDs ML for each minimum pixel unit. This will be described in detail with reference to FIGS. 6A and 6B.

FIG. 6A is a view illustrating individualized modules 1 formed by transferring respective red micro LEDs R, green micro LEDs G, and blue micro LEDs B to a relay wiring substrate 2 at a regular pitch distance in the diagonal direction so that each of the individualized modules 1 has a 3×3 pixel arrangement including three red micro LEDs R, three green micro LEDs G, and three blue micro LEDs B.

The individualized modules 1 as illustrated in FIG. 6A may be formed by transferring the micro LEDs ML of the first substrate 1 to the relay wiring substrate 2 with a transfer head 4 having holding holes formed at a pitch distance corresponding to a diagonal pitch distance of the micro LEDs ML and by dividing the micro LEDs ML for each minimum pixel unit.

In order to form the individualized modules 1 as illustrated in FIG. 6A, the red micro LEDs R, the green micro LEDs G, and the blue micro LEDs B may be sequentially transferred to the relay wiring substrate 2. This is an example, and thus the transfer order of the micro LEDs ML is not limited thereto.

First, the transfer head 4 may hold the red micro LEDs R of the first red micro LED substrate with the red micro LEDs R and transfer the red micro LEDs R to the relay wiring substrate 2. In this case, since the transfer head 4 has the holding holes formed at the pitch distance corresponding to a diagonal pitch distance of the red micro LEDs arranged on the first red micro LED substrate, the red micro LEDs R may be transferred in the diagonal direction.

Then, in the same manner as in the case of the red micro LEDs R, the transfer head 4 may hold the green micro LEDs G from the first green micro LED substrate with the green micro LEDs G and transfer the same to the relay wiring substrate 2, and then may hold the blue micro LEDs B from the first blue micro LED substrate with the blue micro LEDs B and transfer the same to the relay wiring substrate 2.

As above, the transfer head 4 may transfer the red, green, and blue micro LEDs R, G, and B to the relay wiring substrate 2 while reciprocating three times between the respective first substrates 101 with the micro LEDs R, G, and B and the relay wiring substrate 2 so that three red micro LEDs R, three green micro LEDs G, and three blue micro LEDs B may form a 3×3 pixel arrangement. The relay wiring substrate 2 may be cut for each minimum pixel unit of the micro LEDs ML to form the individualized modules 1.

As illustrated in FIG. 6A, the red, green, and blue micro LEDs R, G, and B may be arranged in three-dimensional arrays to form the individualized modules 1. The order of the pixel arrangement in row 1 and column 1 of each of the individualized modules 1 in three-dimensional arrays is such that a red micro LED R, a green micro LED G, and a blue micro LED B are sequentially arranged in a row. The order of the pixel arrangement in row 2 and column 1 of the individualized module 1 is such that a blue micro LED B, a red micro LED R, and a green micro LED G are sequentially arranged in a row. The order of the pixel arrangement in row 3 and column 1 of the individualized module 1 is such that a green micro LED G, a blue micro LED B, and a red micro LED R are sequentially arranged in a row. The individualized modules 1 may arranged in three-dimensional arrays in the pixel arrangement order described above.

When the position of one individualized module 1 located on the upper leftmost side of FIG. 6A is referred to as row 1 and column 1, the order of the pixel arrangement in row 1 and column M is the same as that of the individualized module 1 in row 1 and column 1, and the order of the pixel arrangement in row N and column 1 is the same as that of the individualized module 1 in row 1 and column 1. With such configuration, although the individualized modules 1 are arranged adjacent to each other on a circuit board 201, pixels may be implemented in the horizontal and vertical directions with respect to a specific micro LED ML.

individualized modules 1 illustrated in FIG. 6B may be formed by transferring respective red, green, and blue micro LEDs R, G, and B to a relay wiring substrate 2 at a two-fold pitch distance P (m) in the x-direction and at a two-fold pitch distance P (n) in the y-direction so that the micro LEDs R, G, and B may be arranged in two-dimensional arrays.

A transfer head 4 having holding holes formed at a pitch distance corresponding to a pitch distance of micro LEDs ML transferred to the relay wiring substrate 2 may sequentially transfer the red micro LEDs R, the blue micro LEDs B, and the green micro LEDs G to the relay wiring substrate 2. This is an example, and thus the transfer order of the micro LEDs ML is not limited thereto.

First, during first transfer, the transfer head 4 holds the red micro LEDs R from the first red micro LED substrate with the red micro LEDs R and transfers the red micro LEDs R to the relay wiring substrate 2. During second transfer, the transfer head 4 holds the blue micro LEDs B from the first blue micro LED substrate with the blue micro LEDs B, is positioned to the right side in the drawing by a distance corresponding to an x-direction pitch distance of the micro LEDs ML with respect to the red micro LEDs R already transferred on the relay wiring substrate 2, and collectively transfers the blue micro LEDs B to the relay wiring substrate 2. Then, during third transfer, the transfer head 4 selectively holds the green micro LEDs G, is positioned to the lower side in the drawing by a distance corresponding to a y-direction pitch distance of the micro LEDs ML with respect to the blue micro LEDs B transferred on the relay wiring substrate 2 during second transfer, and collectively transfers the green micro LEDs G to the relay wiring substrate 2.

Then, during fourth transfer, the transfer head 4 transfers an additional micro LED ML to a margin area in an empty 2×2 pixel arrangement to form a 2×2 pixel arrangement with a total of 4 micro LEDs R, G, and B. Thus, light emission characteristics or visibility of the micro LEDs ML may be supplemented, and when a missing micro LED ML exists because the micro LEDs ML are not transferred properly or a defective micro LED F exists, a normal micro LED ML may be additionally mounted, which may improve image quality of a display device. The additionally transferred micro LED ML may be any one of red, green, and blue micro LEDs R, G, and B, and it will be described below that the blue micro LED B is additionally transferred.

During fourth transfer, the transfer head 4 may hold the blue micro LED B and transfer the same to the relay wiring substrate 2. Thus, four micro LEDs R, G, and B may form a 2×2 pixel arrangement and may be defined as a minimum pixel unit.

As shown in FIG. 6B, the four micro LEDs R, G, and B may form a 2×2 pixel arrangement on the relay wiring substrate 2, and the relay wiring substrate 2 may be cut so that the individualized modules 1 may be formed in number corresponding to 2m×2n. In this case, m and n are natural numbers.

Referring to FIG. 6B, the individualized modules 1 may be formed by dividing the micro LEDs ML for each 4×4 pixel arrangement. The minimum pixel unit of each of the individualized modules 1 is in the form of a two-dimensional array in which a blue micro LED B is located on the right side of a red micro LED R, a green micro LED G is located below the blue micro LED B, and a blue micro LED B is located below the red micro LED R.

When a 2×2 pixel arrangement of the four micro LEDs R, G, and B in FIG. 6B is referred to as row 1 and column 1, micro LEDs ML in row 1 and column 1, row 1 and column 2, row 2 and column 1, and row 2 and column 2 may constitute one individualized module 1. When the position of this individualized module 1 is referred to as row 1 and column 1, individualized modules 1 each being composed of a 4×4 pixel arrangement are repeatedly arranged in number corresponding to a natural number multiple. With such configuration, even when a plurality of individualized modules 1 are arranged adjacent to each other on a circuit board 201, the minimum pixel units of the individualized modules 1 may have the substantially same distribution.

The pixel arrangement of the individualized modules 1 is not limited to those described above with reference to FIGS. 5, 6A, and 6B, and the individualized modules 1 may be formed so that each of the individualized modules 1 has a pixel arrangement that can constitute a minimum pixel unit.

The micro LED display device 1000 according to the present disclosure may be manufactured with only normal individualized modules 6 through the micro LED transfer method according to the present disclosure. Thus, the micro LED display device 1000 may have a high degree of reliability.

As described above, the present disclosure has been described with reference to the exemplary embodiments. However, those skilled in the art will appreciate that various modifications, additions and substitutions are possible, without departing from the scope and spirit of the present disclosure as disclosed in the accompanying claims.

### DESCRIPTION OF THE REFERENCE NUMERALS IN THE DRAWINGS

1: individualized module
2: relay wiring substrate
3: relay wiring part
3a: first connection pad, bonding pad
3b: second connection pad, connection pad
3c: internal wiring
4: transfer head
5: defective individualized module
6: normal individualized module
7: repair head
8: solder bump
1000: micro led display device

1. A micro LED transfer method, comprising:
transferring micro LEDs of a first substrate to a relay wiring substrate provided with a relay wiring part;
cutting the relay wiring substrate to which the micro LEDs are transferred into a plurality of individualized modules; and
transferring a normal individualized module among the individualized modules to a second substrate.

2. The micro LED transfer method of claim 1, wherein the transferring of the normal individualized module is performed by collectively transferring, by a transfer head, a plurality of normal individualized modules including the normal individualized module in which a defective individualized module is replaced with a normal individualized module by a repair head to the second substrate.

3. The micro LED transfer method of claim 1, wherein the transferring of the normal individualized module is performed by individually transferring, by a transfer head, only the individualized module to the second substrate.

4. The micro LED transfer method of claim 1, further comprising:
molding an upper portion of the relay wiring substrate after the transferring of the micro LEDs.

5. The micro LED transfer method of claim 1, further comprising:
testing the micro LEDs by applying electricity to the relay wiring part,
wherein an individualized module with a normal micro LED is specified as a normal individualized module.

6. The micro LED transfer method of claim 5, wherein the testing of the micro LEDs is performed after the transferring of the micro LEDs or the cutting of the relay wiring substrate.

7. A micro LED display device, comprising:
a circuit board provided with a circuit wiring part; and
an individualized module electrically connected to the circuit wiring part on an upper surface of the circuit board, and provided with micro LEDs located on a relay wiring substrate provided with a relay wiring part so as to be electrically connected to the relay wiring part.

8. The micro LED display device of claim 7, wherein the individualized module is provided discontinuously on the circuit board.

9. The micro LED display device of claim 7, wherein the micro LED is a flip-chip micro LED.
